(19) United States
(12) Patent Application Publication
(10) Pub. No.: US 2003/0090876 A1
(43) Pub. Date: May 15, 2003

(54) Module including one or more chips

(76) Inventors: Rune Groppfeldt, Linkoping (SE); Leif Ljunggvist, Nykoping (SE); Ulf Wahlstrom, Norrkoping (SE); Mark Tober, Norrkoping (SE); Sven-Tuve Persson, Linkoping (SE); Bjorn Ekstrom, Norrkoping (SE)

Correspondence Address: Alfred J Mangels, 4729 Cornell Road, Cincinnati, OH, 45241-2433, US

(21) Appl. No.: 10/149,313

(22) PCT Filed: Dec. 7, 2000
(86) PCT No.: PCT/SE00/02462

(30) Foreign Application Priority Data
Dec. 16, 1999 (SE) 9904622-9

(51) Int. Cl. H05K 7/20

(52) U.S. Cl. 361/715

(57) ABSTRACT

A module comprising one or more chips and a carrier. The invention is characterised in that the carrier (6) supports a conductive layer (7) that includes a number of conductors; in that chips (2-5; 10; 27-30) are mounted directly on conductive layer (7) of the carrier (6); in that said chips (2-5; 10, 27-30) are connected electrically directly to the conductor system (7); and in that the carrier-supported conductive layer includes terminals (8,9) in the form of solder balls or corresponding devices disposed on the same side of the carrier (6) as said chips.

The present invention relates to a module which includes one or more chips and which is intended to be mounted on a circuit board (PCB) of known kind.

Development in the electronic industry constantly places higher demands on the integration of different components. Different systems become constantly smaller, performances increase and the thermic conditions become more difficult to overcome. At the same time, it is anticipated that multichip systems will become cheaper.

According to known technology, chips are mounted in packages, where one or more chips may be found in one and the same package. In turn, the package is provided with contact pins intended for connection to conductors on a circuit board. Mounting is conventionally effected as QFP (Quad Flat Pac), PGA (Pin Grid Array) or BGA (Ball Grid Array).

Chip packaging is an expensive process which requires a relatively large number of working steps, where each chip must be connected to a substrate internally of the package, and where the substrate shall be connected to the lead frame. As a result of all connections, the package will have a relatively large surface in comparison with the surface of a respective packaged chip.

Because the packages often include plastic encasements, cooling of these known packages represents a problem. When such a package is mounted on a circuit board, the heat generated inside the package will be enclosed therein. Function of the chip is impaired, when the temperature becomes too high. The provision of an air exchange which is sufficiently effective to achieve adequate cooling is often problematic. This cooling problem will, of course, exacerbate with the number of packages and other components on the circuit board.

Another problem with known technology resides in the additional inductance caused by connection leads and lead frames, among other things.

The present invention solves the problems associated with conventional packaging technology.

The present invention thus relates to a module which includes one or more chips and a carrier, wherein the module is characterised in that a conductive layer that comprises a number of conductors is disposed on the carrier; in that one or more chips is/are mounted directly on the carrier-supported conductive layer, in that said one or more chips is/are connected electrically directly to the conductor system; and in that the carrier-supported conductive layer is provided with terminals in the form of solder balls or corresponding elements placed on the same side of the carrier as the chip or chips.

The invention will now be described in more detail partly with reference to an exemplifying embodiment of the invention shown in the accompanying drawing, in which

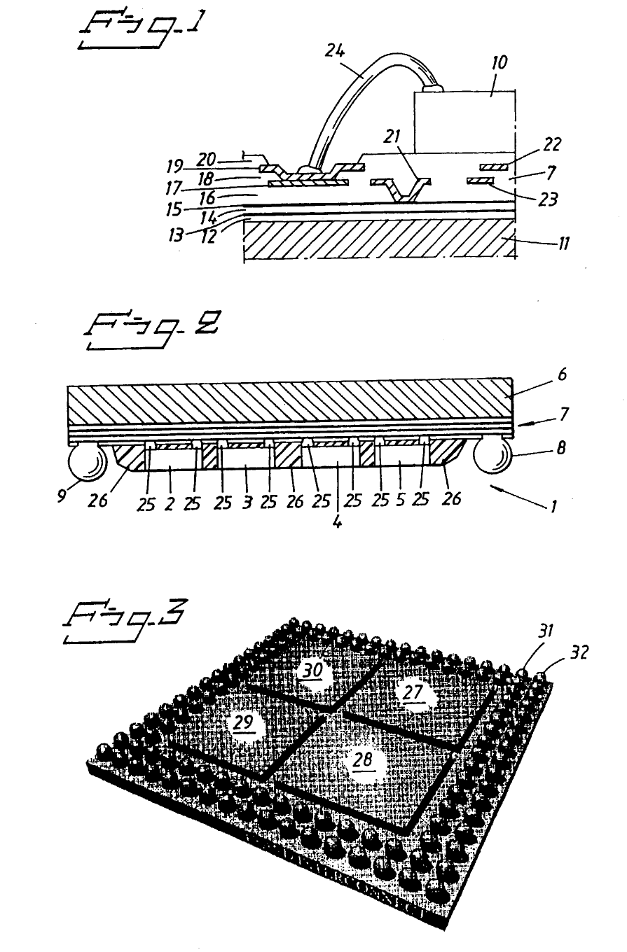

FIG. 1 is a sectional view of part of a conductive layer produced by a thin film technique, and also shows a wire bonded chip;

FIG. 2 is a sectional view of a multichip module according to the present invention; and

FIG. 3 is a perspective view over a completed multichip module according to the present invention.

FIG. 2 is a sectional view of an inventive module 1 that includes one or more chips 2, 3, 4, 5 and a carrier 6.

In accordance with the invention, the carrier 6 supports a conductive layer 7 which includes a number of electric conductors. The conductive layer 7 is shown in FIG. 2 in alternating light and dark parts, which illustrate conductors and intermediate insulating layers respectively. In accordance with the invention, the chips 2-5 are mounted directly on the carrier-supported conductive layer 7, where said chips are connected electrically directly to the conductor system in the conductive layer. According to the invention the conductive layer 7 of the carrier 6 also includes terminals in the form of solder balls 8, 9 or technically equivalent devices placed on the same side of the carrier 6 as the chips 2-5. These solder balls 8, 9 are connected electrically to the conductive layer 7, thereby connecting the terminals 8, 9 with said chips through the medium of the conductor system 7.

Alternatively, the solder balls may be replaced with other electrically conductive and adhesive materials, such as electrically conductive glue.

The illustrated module 1 is intended to be connected electrically to a conventional circuit board (PCB) through the medium of said solder balls 8, 9.

The reference numeral 26 in FIG. 2 identifies plastic that has been moulded or cast between the chips. Such plastic is not always necessary.

According to one highly preferred embodiment of the invention, the conductor system 7 is built-up by means of known thin film technology.

FIG. 1 illustrates a conductive layer of the present kind. FIG. 1 is a sectional view of part of the conductive layer 7. The reference numeral 11 identifies the carrier, the reference numeral 12 identifies an insulating layer, such as a layer of polymer material, the reference numeral 13 identifies a conductive metal layer, the reference numeral 14 identifies an insulating layer, the reference numeral 15 identifies a conductive metal layer, the reference numeral 16 identifies an insulating layer, the reference numeral 17 identifies a metal layer, the reference numeral 18 identifies an insulating layer, the reference numeral 19 identifies a metal layer, and the reference numeral 20 identifies an insulating layer. The parts 21, 22, 23 are thus conductive metal layers formed in the conductive layer 7, as in the illustrated section.

However, it is possible to use thick-film technology instead of thin-film technology in certain cases.

In the FIG. 1 embodiment, a chip 10 is wire-bonded to the conductive layer by means of a wire 24. This constitutes one way of connecting a chip electrically to the conductor system. When this method of connecting the chip is applied, the chip 10 itself is glued firmly to the upper side of the conductive layer 7.

According to another preferred method, the chip is connected to the conductor system by soldering to terminals on the conductor system, as illustrated in FIG. 2. The reference numeral 25 in FIG. 2 identifies solder balls by means of which terminals on respective chips 2-5 are connected electrically to terminals on the conductive layer 7.

According to a further embodiment the chips 2-5 are connected to the conductor system by means of glueing with an electrically conductive glue.

The invention thus eliminates the need to package the chip, as the entire module is mounted directly on a circuit board instead. This eliminates a number of the working steps that would otherwise be required, therewith lowering the price.

Moreover, the invention also provides advantages. For instance, with respect to circuit cooling, the heat will be transported upwards in the case of the FIG. 2 embodiment. Thus, the cooling surface will consist of the entire upper side of the carrier 6. Extremely effective cooling is achieved, when the carrier is comprised of a material that has good thermal conductivity, such as silicon or aluminium. When applicable, devices that make cooling more effective can also be mounted on the carrier 6.

The ability to integrate passive components, such as inductors, capacitors and resistors on the carrier, in addition to the chip or chips, is highly important in certain applications. In this regard, it may be essential to cut down parasitic inductances particularly at high frequencies. With this in mind, it is preferred to produce the carrier from a material that has a high dielectric constant, so that passive high frequency components, such as glass or ceramic components, can be applied.

In accordance with the invention, the solder balls 8, 9 are placed in contact with the circuit board. The balls are placed suitably along the outer edges of the module, as illustrated in FIG. 3. In the FIG. 3 illustration, an outer row 31 and an inner row 32 of solder balls extend around the module. These balls are connected to the chips 27-30 via the conductive layer 7. A module may include as many as one thousand balls.

It will be evident that the present invention simplifies the construction of modules that include a plurality of chips.

Although a number of exemplifying embodiments have been described in the foregoing, it will be obvious that the module may include more chips, that passive components may be included, and that the conductive layer may have some other configuration. The person skilled in this art will be capable of modifying construction to suit the module to be produced.

The present invention shall not therefore be considered to be restricted to the aforedescribed and illustrated embodiments thereof, as modifications and variations can be made within the scope of the accompanying claims.

1. A module which includes one or more chips and a carrier, characterised in that the carrier (6) supports a conductive layer (7) that comprises a number of conductors; in that chips (2-5; 10; 27-30) are mounted directly on the conductive layer (7) of the carrier (6); in that said chips (2-5; 10; 27-30) are connected electrically directly to the conductor system (7); and in that the carrier-supported conductive layer includes terminals (8, 9) in the form of solder balls or corresponding devices placed on the same side of the carrier (6) as said chip or chips.

2. A module according to claim 1, characterised in that the conductor system (7) is constructed with the aid of thin-film technology.

3. A module according to claim 1 or 2, characterised in that said chip or chips (2-5; 27-30) is/are connected to the conductor system (7) by soldering said chip or chips to terminals on the conductor system.

4. A module according to claim 1 or 2, characterised in that said chip or chips (10) is/are wire bonded to the conductor system.

5. A module according to claim 1 or 2, characterised in that said chip or chips (2-5; 10; 27-30) is/are glued to the conductor system (7) with an electrically conductive glue.

6. A module according to claim 1, 2, 3, 4 or 5, characterised in that the carrier (6) is comprised of a material of high thermal conductivity, such as silicon or aluminium.

7. A module according to claim 1, 2, 3, 4 or 5, characterised in that the carrier (6) is comprised of a material that has a high dielectric constant, such as glass or ceramic material, so as to reduce inductive losses at high frequencies.
